(19) United States
(12) Patent Application Publication
(10) Pub. No.: US 2014/0373867 A1
(43) Pub. Date: Dec. 25, 2014

(54) CLEANING METHOD AND SUBSTRATE PROCESSING APPARATUS

(71) Applicant: Tokyo Electron Limited, Tokyo (JP)

(72) Inventor: Akitoshi HARADA, Miyagi (JP)

(21) Appl. No.: 14/306,548

(22) Filed: Jun. 17, 2014

(30) Foreign Application Priority Data
Jun. 25, 2013 (JP) 2013-132719

(51) Int. Cl. C23C 16/44; C23C 16/02; H01J 37/32

(52) U.S. Cl. CPC C23C 16/4405; H01J 37/32862; C23C 16/0245
USPC 134/1.1; 156/345.24

(57) ABSTRACT

A cleaning method, which is performed when using a substrate processing apparatus including at least an electrostatic chuck to receive a substrate and performing a plasma process on the substrate, for removing a deposit containing titanium and attached to the electrostatic chuck, is provided. In the method, the deposit containing titanium is reduced by plasma generated from a first process gas containing a reducing gas. Next, the reduced deposit containing titanium is removed by plasma generated from a second process gas containing a fluorine-based gas. A fluorocarbon based deposit deposited when removing the reduced deposit containing titanium by the plasma generated from the second process gas containing the fluorine-based gas is removed by plasma generated from a third process gas containing oxygen.

### CROSS-REFERENCE TO RELATED APPLICATIONS

This patent application is based upon and claims the benefit of priority of Japanese Patent Application No. 2013-132719, filed on Jun. 25, 2013, the entire contents of which are incorporated herein by reference.

### BACKGROUND OF THE INVENTION

1. Field of the Invention

The present invention relates to a cleaning method and a substrate processing apparatus.

2. Description of the Related Art

A plasma processing apparatus is well known that performs a predetermined treatment such as etching on a substrate such as a wafer for semiconductor devices by using plasma as a substrate processing apparatus. The plasma processing apparatus is configured to include a processing chamber that generates plasma therein, a mounting table on which a wafer disposed in the processing chamber is placed, an electrostatic chuck (ESC) arranged on a top surface of the mounting table to hold the wafer and the like.

The electrostatic chuck is generally designed to have its diameter smaller than that of the wafer placed thereon, and to have a slight clearance between an outer periphery of the electrostatic chuck and a back surface of the wafer. When etching the wafer by plasma interaction, a reaction product is deposited in the clearance, on an inner wall of the processing chamber and the like. The reaction product deposited on the electrostatic chuck causes an error in attracting the wafer and prevents a preferable plasma treatment.

Because of this, a cleaning treatment for removing the deposited reaction product in the processing chamber at predetermined intervals and a treatment for adjusting the atmosphere in the processing chamber are performed. More specifically, Japanese Laid-Open Patent Application Publication No. 2008-519431 discloses a waferless dry cleaning (WLDC) treatment that dry-cleans the inside of the processing chamber without using a wafer as a method for removing the reaction product.

Conventionally, the WLDC treatment using oxygen (O₂) gas has been adopted in a cleaning treatment after etching a silicon-based film. However, in recent years, titanium-containing films such as a titanium nitride (TiN) film or the like are sometimes used as a mask for a film to be etched in a plasma etching process. A titanium-containing reaction product that deposits on the electrostatic chuck and the like when performing the etching process by using the TiN film as the mask, however, is difficult to remove by the WLDC treatment using O₂ gas.

### SUMMARY OF THE INVENTION

Accordingly, in response to the above discussed problems, embodiments of the present invention provide a cleaning method that can remove a reaction product containing titanium deposited on an electrostatic chuck.

According to one embodiment of the present invention, there is provided a cleaning method, which is performed when using a substrate processing apparatus including at least an electrostatic chuck to receive a substrate and performing a plasma process on the substrate, for removing a deposit containing titanium and attached to the electrostatic chuck. In the method, the deposit containing titanium is reduced by plasma generated from a first process gas containing a reducing gas. Next, the reduced deposit containing titanium is removed by plasma generated from a second process gas containing a fluorine-based gas. A fluorocarbon based deposit deposited when removing the reduced deposit containing titanium by the plasma generated from the second process gas containing the fluorine-based gas is removed by plasma generated from a third process gas containing oxygen.

According to another embodiment of the present invention, there is provided a substrate processing apparatus that includes a processing chamber, an electrostatic chuck provided in the processing chamber and configured to hold a substrate, an electrode plate provided in the processing chamber and facing the electrostatic chuck, a gas supply part to supply a process gas to a space sandwiched between the electrostatic chuck and the electrode plate, a high frequency power source configured to convert the process gas supplied to the space by the gas supply part to plasma by supplying high frequency power to at least one of the electrostatic chuck and the electrode plate, and a control unit configured to control the substrate processing apparatus. The control unit performs control of reducing a deposit containing titanium attached to the electrostatic chuck by plasma generated from a first process gas containing a reducing gas, removing the reduced deposit containing titanium by plasma generated from a second process gas containing a fluorine-based gas, and removing a fluorocarbon-based deposit deposited on the electrostatic chuck when removing the reduced deposit containing titanium by the plasma generated from the second gas containing the fluorine-based gas by plasma generated from a third process gas containing oxygen.

Additional objects and advantages of the embodiments are set forth in part in the description which follows, and in part will become obvious from the description.

### BRIEF DESCRIPTION OF THE DRAWINGS

FIG. 1 is a schematic configuration diagram illustrating an example of a plasma processing apparatus according to an embodiment of the present invention;

FIGS. 2A and 2B are schematic diagrams for illustrating a deposition form of a reaction product during an etching process using a titanium-containing film as a mask performed by the substrate processing apparatus according to an embodiment of the present invention;

FIGS. 3A through 3D are schematic diagrams for illustrating a principle of wafer attraction by an electrostatic chuck;

FIG. 4 is a flowchart illustrating an example of a cleaning method according to an embodiment of the present invention; and

FIGS. 5A through 5C are schematic diagrams for illustrating an example of the cleaning method according to an embodiment of the present invention.

### DETAILED DESCRIPTION OF THE PREFERRED EMBODIMENTS

A description is given below of embodiments of the present invention, with reference to accompanying drawings. Note that elements having substantially the same functions or features maybe given the same reference numerals and overlapping descriptions thereof may be omitted.

[Substrate Processing Apparatus]

To begin with, a description is given below of an example of a substrate processing apparatus that can implement a cleaning method of the embodiments. The substrate processing apparatus that can perform the cleaning method of the embodiments is not limited to a particular form, but a parallel plate type (which is also called a capacitively-coupled) plasma processing apparatus is taken as an example that can perform a plasma process such as an RIE (Reactive Ion Etching) process, an ashing process and the like on a semiconductor wafer (which is hereinafter called a wafer W) that is an object to be processed.

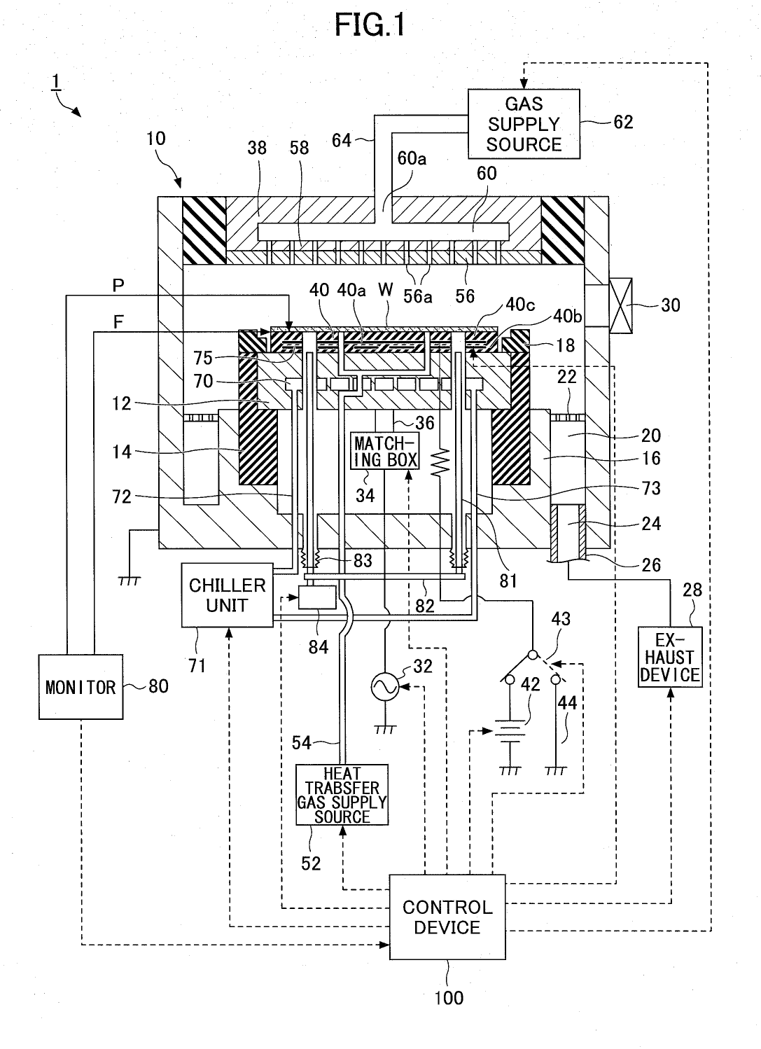

FIG. 1 illustrates an example of a schematic configuration of the substrate processing apparatus according to an embodiment.

The plasma processing apparatus 1 according to the embodiment includes a cylindrical chamber (processing chamber 10) made of metal such as aluminum, stainless steel or the like. The processing chamber 10 is grounded. In the processing chamber 10, a plasma process such as the cleaning method of the embodiment described later or an etching process can be performed on the object to be processed.

In the processing chamber 10, there is a mounting table 12 for receiving a semiconductor wafer w (which is hereinafter called a wafer W) provided in the processing chamber 10. The mounting table 12, for example, made of aluminum, is supported by a cylindrical support 16 vertically extending upward from the bottom of the processing chamber 10 through an insulting cylindrical holding part 14. A focus ring 18 made of, for example, quartz, and surrounding an upper surface of the mounting table 12 in a ring shape is arranged on an upper surface of the cylindrical holding part 14. The focus ring 18 focuses plasma generated above the mounting table 12 onto the wafer W.

An exhaust passage 20 is formed between an inner wall of the processing chamber 10 and an outer wall of the cylindrical support 16. A ring-shaped baffle plate 22 is attached to the exhaust passage 20. An exhaust port 24 is provided in a bottom part of the exhaust passage 20, and is connected to an exhaust device 28 through an exhaust pipe 26.

The exhaust device 28 includes a vacuum pump (not shown in the drawing), and reduces a pressure in the processing chamber 10 to a predetermined degree of vacuum. A gate valve 30 that opens and closes when carrying in/out the wafer W is attached to a side wall of the processing chamber 10.

The mounting table 12 is electrically connected to a high frequency power source 32 for plasma generation through a power feeding bar 36 and a matching box 34. The high frequency power source 32 supplies high frequency power, for example 60 MHz, to the mounting table 12. In this manner, the mounting table 12 also functions as a lower electrode.

A shower head 38 is provided in a ceiling part of the processing chamber 10 as an upper electrode having a ground potential. The high frequency power for plasma generation from the high frequency power source 32 is capacitively applied to the mounting table 12 and the shower head 38.

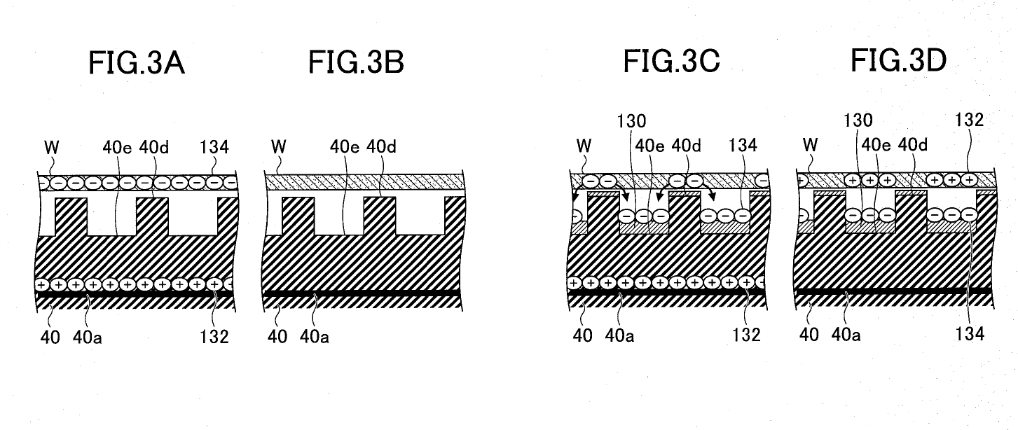

There is an electrostatic chuck (ESC) 40 to hold the wafer W by an electrostatic attractive force provided on an upper surface of the mounting table 12. The electrostatic chuck 40 sandwiches a sheet-like chuck electrode 40a made of a conductive film between dielectric layers 40b and 40c of a pair of dielectric members. A direct voltage source 42 is connected to the chuck electrode 40a through a switch 43. Here, in general, as illustrated in FIGS. 3A through 3D described later, convex portions 40d and concave portions 40e are formed in a wafer receiving surface of the electrostatic chuck 40. These convex portions 40d and the concaves portion 40e can be formed by, for example, embossing the electrostatic chuck 40 with the convex portions 40d.

The electrostatic chuck 40 attracts the wafer W on the chuck by a coulomb force by allowing a voltage to be applied thereto from the direct voltage source 42. Moreover, when the voltage is not applied to the chuck electrode 40a, the chuck electrode 40a is in a state connected to ground by the switch 43. Hereinafter, the state in which the voltage is not applied to the chuck electrode 40a means the state in which the chuck electrode 40a is grounded.

The electrostatic chuck 40 includes a coulomb type electrostatic chuck with the dielectric layers 40b and 40c having a volume resistivity of 1×10¹⁴ Ωcm or more, a J-R (Jhonsen-Rahbek) force type electrostatic chuck having a volume resistivity of about 1×10⁹⁻¹² Ωcm, and a JR force+coulomb type electrostatic chuck formed by spraying alumina or the like and having a volume resistivity of 1×10¹²⁻¹⁴ Ωcm. In the substrate processing apparatus 1 according to the embodiment, any type of the electrostatic chuck can be used.

A heat transfer gas supply source 52 supplies a heat transfer gas such as helium (He) gas to a back surface of the wafer W on the electrostatic chuck 40 through a gas supply line 54.

The shower head 38 in the ceiling part includes an electrode plate 56 including many gas discharge holes 56a and a detachable electrode support 58 that supports the electrode plate 56. A buffer chamber 60 is provided inside the electrode support 58. A gas supply source 62 is coupled to a gas introduction port 60a of the buffer chamber 60 through a gas supply pipe 64. By such a configuration, a desired process gas is supplied into the processing chamber 10 from the shower head 38.

The shower head 38 in the ceiling part includes the electrode plate 56 including many of the gas discharge holes 56a and the detachable electrode support 58 that supports the electrode plate 56. The buffer chamber 60 is provided inside the electrode support 58. The gas supply source 62 is coupled to the gas introduction port 60a of the buffer chamber 60 through the gas supply pipe 64. The gas supply source 62 can control each of a variety of process gases independently, and can supply the variety of process gases into the processing chamber 10. By doing this, a desired gas is supplied from the shower head 38 into the processing chamber 10.

Plural support pins 81 (e.g., three pins) are provided inside the mounting table 12 in order to move the wafer W up and down between an external transfer arm (not shown in the drawing) and the inside of the processing chamber 10. The plural support pins 81 move up and down by the force of a motor 84 transmitted through a coupling member 82. Bottom bellows 83 are provided at through-holes for the support pins 81 that penetrate to the outside of the processing chamber 10, and maintain an air tight state between a vacuum side in the processing chamber 10 and an atmosphere side.

Furthermore, a magnet extending annularly or concentrically (not shown in the drawing) may be arranged around the processing chamber 10, for example, at two stages located at an upper position and a lower position.

Ordinarily, a refrigerant pipe 70 is provided inside the mounting table 12. A coolant of a predetermined temperature is supplied and circulated through the refrigerant pipe 70 from a chiller unit 71 through pipes 72 and 73. In addition, a heater 75 is embedded inside the electrostatic chuck 40. An alternating voltage is applied to the heater 75 from an alternate-current source (which is not shown in the drawing). A processing temperature of the wafer W on the electrostatic chuck 40 is adjusted to a desired temperature by cooling by using the chiller unit 71 and heating by using the heater 75.

The substrate processing apparatus 1 may be configured to include a monitor 80 for monitoring a pressure of the heat transfer gas supplied to the back surface of the wafer W and a leakage flow rate of the heat transfer gas leaking from the back surface of the wafer W. When monitoring the pressure of the heat transfer gas, a pressure value P of the heat transfer gas is measured by a pressure sensor (not shown in the drawing) attached to the back surface of the wafer W. Moreover, the leakage flow rate F of the heat transfer gas is measured by, for example, a flow rate sensor (not shown in the drawing) attached in the neighborhood of a side surface of the wafer W.

The substrate processing apparatus 1 includes, for example, the gas supply source 62, the exhaust device 28, the heater 75, the direct voltage source 42, the switch 43, the matching box 34, the high frequency power source 32, the heat transfer gas supply source 52, the motor 84, and a control unit 100 that controls the operation of the chiller unit 71. The control unit 100 includes a CPU (Central Processing Unit), a ROM (Read Only Memory), and a RAM (Random Access Memory) (which are not shown in the drawing). The CPU executes at least a cleaning treatment of the embodiment described later in accordance with a variety of recipes stored in memory areas. In the recipes, control information of the apparatus corresponding to process conditions is described such as a process time, a pressure (gas exhaustion), a high frequency power and voltage, various process gas flow rates, a temperature inside the chamber (e.g., an upper electrode temperature, a side wall temperature of the chamber, an ESC temperature) and the like. Here, the recipes showing these programs and processing conditions may be stored in a hard disk or a semiconductor memory, or may be configured to be settable at a predetermined location of a memory area, stored in a portable recording medium readable by a computer such as a CD-ROM, a DVD or the like.

[Problems Involved in Electrostatic Chuck]

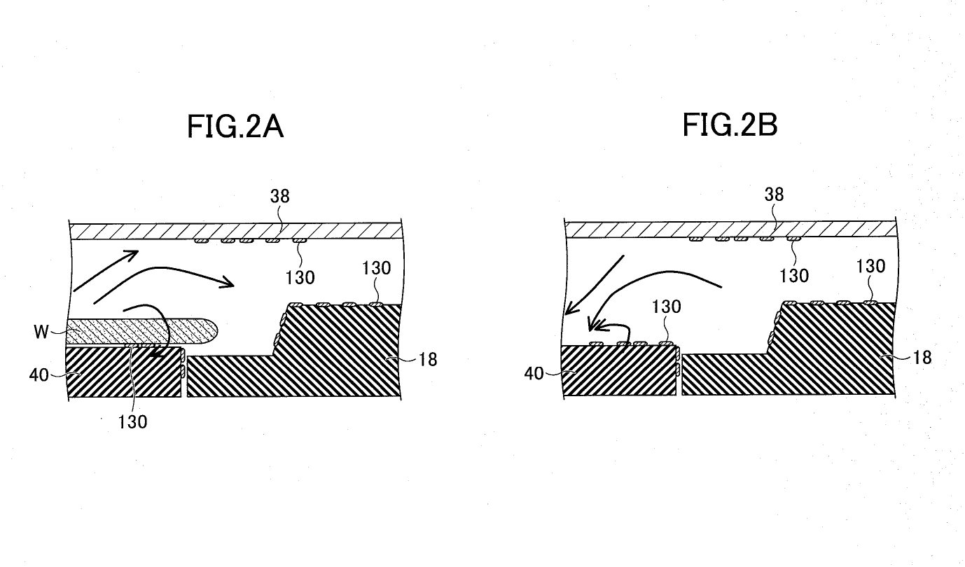

In FIGS. 2A and 2B, schematic diagrams are illustrated to explain a deposition form of a reaction product during the etching process utilizing a titanium-containing film as a mask by the substrate processing apparatus according to the embodiment. More specifically, FIGS. 2A and 2B are schematic diagrams illustrating the neighborhood of the electrostatic chuck in FIG. 1.

As discussed above, the electrostatic chuck 40 is provided on the upper surface of the mounting table 12, and has a function of holding the wafer W by the electrostatic attractive force. When the electrostatic chuck 40 holds the wafer W, the wafer W is placed on the electrostatic chuck 40 so that the upper surface of the electrostatic chuck 40 and the back surface of the wafer W face to each other. In general, the electrostatic chuck 40 is designed to have its diameter smaller than that of the wafer W placed thereon to some degree, and a slight clearance is formed between the outer periphery of the electrostatic chuck 40 and the back surface of the wafer W. This causes the reaction product 130 containing titanium to be attached or deposited on the surface of the electrostatic chuck 40, surfaces of the shower head 38 and the focus ring 18 and the like as illustrated by an arrow of FIG. 2A in performing the etching by utilizing the titanium-containing film as the mask.

In particular, the reaction product 130 deposited on the surface of the electrostatic chuck 40 causes an error in attracting the wafer W to the electrostatic chuck 40. To prevent this, a cleaning treatment for removing the reaction product in the processing chamber 10 is performed at a predetermined timing described later. However, in the conventional WDLC treatment using O₂ gas, as illustrated in FIG. 2B, a problem existed in that the reaction product 130 was unable to be removed because the reaction product 130 containing titanium is oxidized, thereby forming a titanium oxide such as TiO, TiO₂ or the like.

In FIGS. 3A through 3D, schematic diagrams are illustrated to explain a principal of attracting the wafer W by the electrostatic chuck 40. More specifically, FIGS. 3A through 3D are schematic diagrams illustrating the neighborhood of the electrostatic chuck 40 in FIG. 1.

With reference to FIGS. 3A and 3B, a description is given below of an attraction form of the wafer W by the electrostatic chuck 40 when the reaction product 130 containing titanium is not deposited on the electrostatic chuck 40. As illustrated in FIG. 3A, when a positive direct voltage is applied to the chuck electrode 40a by the direct voltage source 42 (see FIG. 1), the chuck electrode 40a is positively charged, and the wafer W placed on the upper surface of the electrostatic chuck 40 is negatively charged. These positive charges 132 and the negative charges 134 are balanced, and the potential difference causes a coulomb force and a J-R force, thereby attracting and holding the wafer W on the electrostatic chuck 40. Then, when the positive direct voltage applied to the chuck electrode 40a by the direct voltage source 42 is removed, as illustrated in FIG. 3B, the negative charges of the wafer W are removed, and the wafer W can be ejected from the electrostatic chuck 40 by the support pins 81 (see FIG. 1).

In contrast, with reference to FIGS. 3C and 3D, a description is given below of an attraction form of the wafer W by the electrostatic chuck 40 when the reaction product 130 containing titanium is deposited on the convex portions 40d and the concave portions 40e in the surface of the electrostatic chuck 40. As illustrated in FIG. 3C, when a positive voltage is applied to the chuck electrode 40a by the direct voltage source 42 (see FIG. 1), the chuck electrode 40a is positively charged to have the positive charges 132 as well as the embodiment in FIG. 3A. However, at least part of the negative charges 134 retained by the wafer W placed on the upper surface of the electrostatic chuck 40 moves to a surface of the reaction product 130 in the concave portions 40e of the electrostatic chuck 40 as illustrated by an arrow in FIG. 3C. This causes the potential difference between the positive charges 132 and the negative charges 134 to be decreased and causes the attractive force to the wafer W by the electrostatic chuck to be decreased. Furthermore, even when the positive direct voltage applied to the chuck electrode 40a by the direct voltage source 42 is removed, the negative charges 134 on the reaction product 130 in the concave portion 40e and the positive charges remaining on the wafer W are balanced, and the potential difference causes the wafer W to be attracted on the electrostatic chuck 40. This causes a driving torque of the support pins 81 to be increased when the support pins 81 eject the wafer W.

The decrease in the attractive force to the wafer W can be confirmed by, for example, measuring a leakage rate of the heat transfer gas such as He gas or the like supplied from the heat transfer gas supply source 52 (see FIG. 1) by the monitor 80 (see FIG. 1). When a deposition amount of the reaction product 130 on the surface of the electrostatic chuck 40 is increased, the leakage rate of the heat transfer gas is increased. In addition, when ejecting the wafer W by lifting the support pins 81 under the condition that the electrostatic attractive force is still remaining due to the remaining electrical charges, the wafer may crack or be moved out of position. Accordingly, a technique for removing the reaction product 130 containing titanium deposited on the electrostatic chuck 40 is very important.

### Cleaning Method According to Embodiment

As a result of the earnest research about the method for removing the reaction product 130 containing titanium, it is determined that the reaction product 130 can be efficiently removed by a cleaning method described later, and the present invention was made.

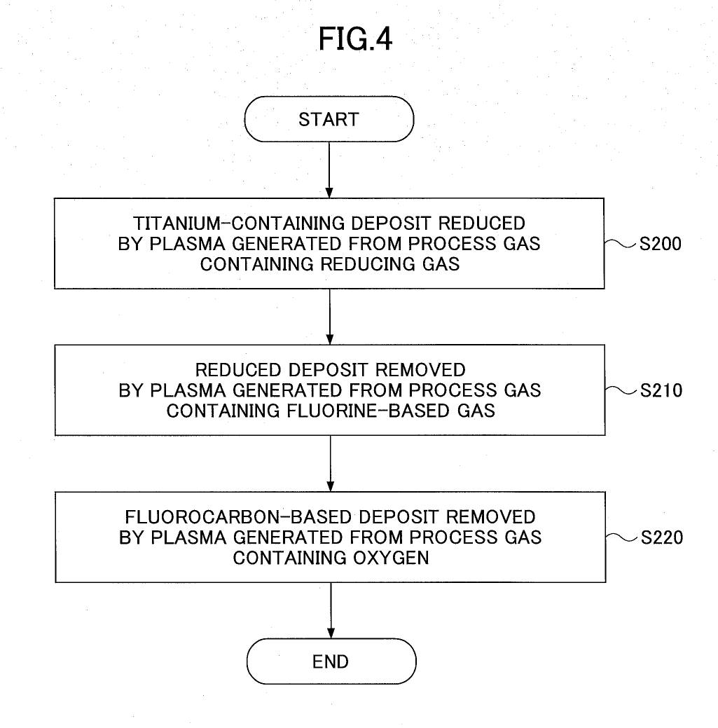

FIG. 4 illustrates a flowchart of an example of a cleaning method of the embodiment. As illustrated in FIG. 4, the cleaning method according to the embodiment is provided as a cleaning method for removing a deposit containing titanium attached to an electrostatic chuck in a substrate processing apparatus that includes at least an electrostatic chuck on which a substrate is placed and performs a plasma treatment on the substrate. The cleaning method of the embodiment includes a first process (S200) of reducing the deposit containing titanium by plasma generated from a process gas containing a reducing gas, a second process (S210) of removing the deposit reduced in the first process by plasma generated from a process gas containing a fluorine-based gas, and a third process (S220) of removing a fluorocarbon-based deposit deposited on the electrostatic chuck in the second process by plasma generated from a process gas containing oxygen.

A detailed description is given below of each of the processes.

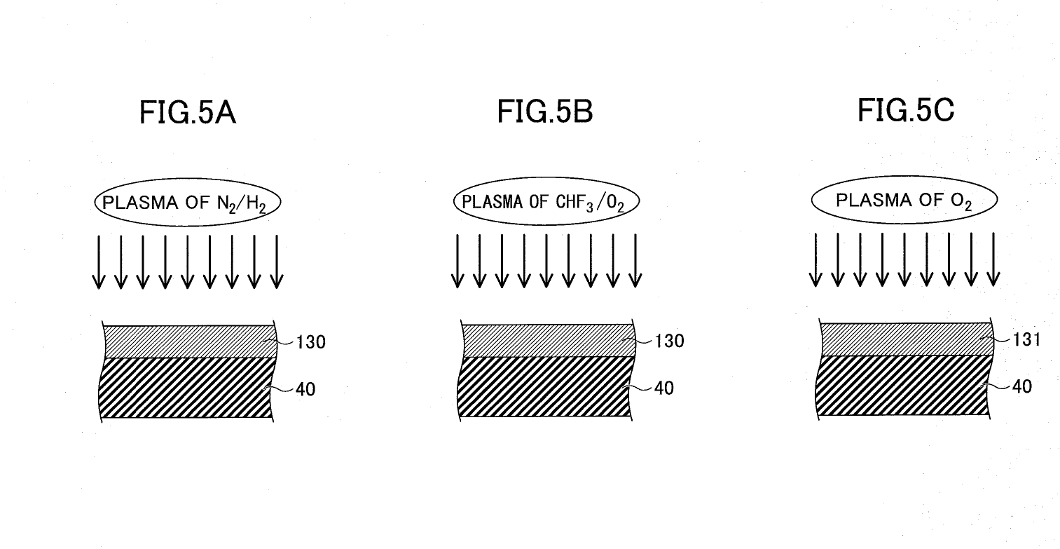

In FIGS. 5A through 5C, schematic diagrams are illustrated to explain an example of the cleaning method of the embodiment. At first, in the first process of S200, as illustrated in FIG. 5A, the reaction product 130 containing titanium and deposited on the electrostatic chuck 40 is reduced by plasma generated from a process gas containing a reducing gas.

The reaction product 130 containing titanium and deposited on the electrostatic chuck 40 is oxidized by oxygen and the like in the system, and mainly exists as a titanium oxide such as TiO, TiO₂ or the like. The titanium oxide cannot be removed by the conventional WLDC process using oxygen gas. Accordingly, in the first process of S200, the titanium oxide is reduced by the plasma generated from the process gas containing the reducing gas.

Although the process gas is not limited to a particular gas as long as the process gas can reduce the titanium oxide, a mixed gas of hydrogen (H₂) gas and nitrogen (N₂) gas is used in the embodiment. More specifically, the titanium oxide is reduced by plasma using H₂ gas, and the titanium oxide is azotized by plasma using N₂ gas to become TiN. This process causes an OH component, a water (H₂O) component and the like within the reaction product 130 to be removed. However, the embodiments of the present invention are not limited to this example, and for example, a reducing gas such as ammonia (NH₃) gas or the like may be used.

Next, as illustrated in FIG. 5B, in the second process of S210, the reaction product 130 containing TiN is mainly removed by the plasma generated from the process gas containing the fluorine-based gas. This process causes a Ti component, an NH component, an OH component, an H₂O component and the like within the reaction product 130 to be removed.

The process gas is not limited to a particular gas as long as the process gas contains the fluorine-based gas, and a mixed gas of trifluoromethane (CHF₃) gas and O₂ gas is used in the embodiment. Here, a fluorine-based gas such as CHF₃ gas or the like may be used alone. Although the reaction product 130 containing Ti is mainly removed in the second process, a fluorocarbon (CF) based reaction product 131 is deposited on the electrostatic chuck 40 in the plasma process using the plasma generated from the process gas containing the fluorine-based gas.

Because of this, as illustrated in FIG. 5C, in the third process of S220, the CF-based reaction product 131 is mainly removed by the plasma generated from the process gas containing O₂ gas. This treatment causes the CF-based reaction product 131 to be removed.

In the cleaning method of the embodiment, as long as the third process is performed at the end, the first process, the second process and the third process maybe repeated. For example, a process group of the first, second and third processes may be repeated, or the third process may be performed at the end after a process group of the first and second processes are repeated.

Here, the cleaning method of the embodiment may be performed after an etching process using a titanium-containing film such as a titanium nitride (TiN) film is performed, for example, on one wafer. Moreover, the cleaning method of the embodiment may be performed after the above-mentioned etching process is performed on a plurality of wafers, for example, fifty wafers. Furthermore, for example, a process time while performing the etching process using the titanium-containing film as the mask is integrated, and the cleaning method of the embodiment may be carried out when the integral time is beyond a predetermined time.

As discussed above, the cleaning method of the embodiment reduces the reaction product 130 containing titanium and deposited on the electrostatic chuck 40 at the first process, and removes the reaction product 130 at the second process. Then, the cleaning method of the embodiment removes the CF-based reaction product 131 deposited on the electrostatic chuck 40 in the second process at the third process. The cleaning method of the embodiment having the above structure can efficiently remove the deposit on the electrostatic chuck 40.

A more detailed description is given below of the present invention with reference to working examples.

### FIRST WORKING EXAMPLE

A description is given of a working example confirming that an electrostatic chuck can be efficiently cleaned by the cleaning method of the embodiments.

A wafer on which a TiN film had been deposited was processed by plasma etching using the TiN film as a mask by using the substrate processing apparatus 1 in FIG. 1. The following analysis was made about an electrostatic chuck that performed the plasma etching process for 169 hours in integral time and an electrostatic chuck that performed the plasma etching process for 996 hours in integral time.

When the wafer is on the electrostatic chuck, the electrostatic chuck was made to attract the wafer by applying a voltage of 1.0 kV, 1.5 kV, 2.0 kV or 2.5 kV to the chuck electrode. Next, He gas was supplied to the back surface of the wafer on the electrostatic chuck so as to set the pressure of the supplied gas at 10, 15, 20, 25 or 30 Torr. Here, in all of the following working examples, a heating temperature of the wafer by the heater 75 in FIG. 1 was set 60 degrees C., and a temperature of the coolant in the chiller unit 71 in FIG. 1 was set at 10 degrees C.

Furthermore, a flow rate of He gas having leaked from the back surface of the wafer was measured under each condition. Here, the flow rate of He gas leaking from the back surface of the wafer is preferred to be equal to or lower than 1 sccm.

TABLE 1 shows a measurement result of the electrostatic chuck having an integral etching time of 169 hours, and TABLE 2 shows a measurement result of the electrostatic chuck having the integral etching time of 996 hours.

TABLE 1

| | | PRESSURE OF He GAS | | | | |
|---|---|---|---|---|---|---|
| | | 10 Torr | 15 Torr | 20 Torr | 25 Torr | 30 Torr |
| CHUCK | 1.0 kV | 0.1 sccm | 0.2 sccm | 0.2 sccm | 0.3 sccm | 0.4 sccm |
| VOLTAGE | 1.5 kV | 0.1 sccm | 0.2 sccm | 0.2 sccm | 0.3 sccm | 0.4 sccm |
| | 2.0 kV | 0.1 sccm | 0.1 sccm | 0.3 sccm | 0.3 sccm | 0.3 sccm |
| | 2.5 kV | 0.1 sccm | 0.1 sccm | 0.2 sccm | 0.2 sccm | 0.3 sccm |

TABLE 2

| | | PRESSURE OF He GAS | | | | |
|---|---|---|---|---|---|---|
| | | 10 Torr | 15 Torr | 20 Torr | 25 Torr | 30 Torr |
| CHUCK | 1.0 kV | 0.6 sccm | 1.0 sccm | 1.5 sccm | 2.5 sccm | 6.0 sccm |
| VOLTAGE | 1.5 kV | 0.6 sccm | 0.9 sccm | 1.2 sccm | 1.6 sccm | 1.9 sccm |
| | 2.0 kV | 0.6 sccm | 0.8 sccm | 1.1 sccm | 1.4 sccm | 1.6 sccm |
| | 2.5 kV | 0.4 sccm | 0.5 sccm | 0.7 sccm | 0.8 sccm | 1.0 sccm |

As clearly noted from a comparison between TABLE 1 and TABLE 2, the electrostatic chuck having the integral etching time of 996 hours has a larger leakage rate of He gas than the integral etching time of 169 hours.

The cleaning treatment was performed for the electrostatic chuck having the integral etching time of 996 hours by using the substrate processing apparatus 1 in FIG. 1. In the cleaning treatment, a process gas containing H₂ gas and N₂ gas was used in the first process (S200); a process gas containing CHF₃ gas and O₂ gas was used in the second process (S210); and a process gas containing O₂ gas was used in the third process (S220).

In addition, after repeating the process group of the first process and the second process three times, the third process was performed.

An analysis similar to the above one was made about the electrostatic chuck after the cleaning treatment. The results of analysis are shown in TABLE 3.

TABLE 3

| | | PRESSURE OF He GAS | | | | |
|---|---|---|---|---|---|---|
| | | 10 Torr | 15 Torr | 20 Torr | 25 Torr | 30 Torr |
| CHUCK | 1.0 kV | 0.1 sccm | 0.2 sccm | 0.2~0.3 sccm | 2.2 sccm | |
| VOLTAGE | 1.5 kV | 0.1 sccm | 0.1 sccm | 0.2 sccm | 0.3~0.4 sccm | 2.2 sccm |
| | 2.0 kV | 0.1 sccm | 0.1 sccm | 0.2 sccm | 0.2 sccm | 0.7 sccm |
| | 2.5 kV-2 | 0.1 sccm | 0.2 sccm | 0.2 sccm | 0.3 sccm | 0.4~0.5 sccm |
| | 2.5 kV-1 | 0.1 sccm | 0.1 sccm | 0.3 sccm | 1.6 sccm | |

From a comparison between TABLE 2 and TABLE 3, it was noted that the leakage rates of He gas improved inmost measurement conditions by performing the cleaning method of the embodiment. In other words, it was noted that the reaction product containing titanium and deposited on the electrostatic chuck can be removed by the cleaning method of the embodiment.

### SECOND WORKING EXAMPLE

A description is given below of another working example conforming that the electrostatic chuck can be efficiently cleaned by the cleaning method of the embodiment.

Similarly to the first working example, a wafer on which a TiN film was deposited was processed by plasma etching by using the substrate processing apparatus 1 of FIG. 1. An analysis similar to the first working example was performed about an electrostatic chuck having performed the plasma etching process for 841 hours in integral time. The results of the analysis are shown in TABLE 4.

TABLE 4

| | | PRESSURE OF He GAS | | | | |
|---|---|---|---|---|---|---|
| | | 10 Torr | 15 Torr | 20 Torr | 25 Torr | 30 Torr |
| CHUCK | 1.0 kV | 0.4 sccm | 0.5 sccm | 0.7 sccm | 0.8 sccm | 1.1 sccm |
| VOLTAGE | 1.5 kV | 0.4 sccm | 0.5 sccm | 0.7 sccm | 0.8 sccm | 1.0 sccm |
| | 2.0 kV | 0.3 sccm | 0.5 sccm | 0.6 sccm | 0.8 sccm | 0.9 sccm |
| | 2.5 kV | 0.4 sccm | 0.6 sccm | 0.7 sccm | 0.9 sccm | 1.1 sccm |

The cleaning treatment was performed for the electrostatic chuck by using the substrate processing apparatus of FIG. 1. In the cleaning treatment, similarly to the first embodiment, a process gas containing H₂ gas and N₂ gas was used in the first process (S200); a process gas containing CHF₃ gas and O₂ gas was used in the second process (S210); and a process gas containing O₂ gas was used in the third process (S220).

Here, the cleaning treatment was performed by three patterns of:

a process of performing the third process after repeating the process group of the first and second processes three times (first pattern);

a process of performing the third process after repeating the process group of the first and second processes nine times (second pattern); and

a process of performing the third process after repeating the process group of the first and second processes thirty times (third pattern).

An analysis similar to the above one was made about the electrostatic chuck after the cleaning treatment under each pattern. The analysis results in the first pattern, the second pattern and the third pattern are shown in TABLE 5, TABLE 6 and TABLE 7.

TABLE 5

| | | PRESSURE OF He GAS | | | | |
|---|---|---|---|---|---|---|
| | | 10 Torr | 15 Torr | 20 Torr | 25 Torr | 30 Torr |
| CHUCK | 1.0 kV | 0.3 sccm | 0.5 sccm | 0.6 sccm | 0.7 sccm | 1.0 sccm |
| VOLTAGE | 1.5 kV | 0.2 sccm | 0.4 sccm | 0.4 sccm | 0.6 sccm | 0.7 sccm |
| | 2.0 kV | 0.2 sccm | 0.3 sccm | 0.4 sccm | 0.5 sccm | 0.6 sccm |
| | 2.5 kV | 0.2 sccm | 0.3 sccm | 0.4 sccm | 0.5 sccm | 0.6 sccm |

TABLE 6

| | | PRESSURE OF He GAS | | | | |
|---|---|---|---|---|---|---|
| | | 10 Torr | 15 Torr | 20 Torr | 25 Torr | 30 Torr |
| CHUCK | 1.0 kV | 0.2 sccm | 0.3 sccm | 0.5 sccm | 0.6 sccm | 0.8 sccm |
| VOLTAGE | 1.5 kV | 0.2 sccm | 0.3 sccm | 0.4 sccm | 0.5 sccm | 0.7 sccm |
| | 2.0 kV | 0.2 sccm | 0.3 sccm | 0.4 sccm | 0.5 sccm | 0.6 sccm |
| | 2.5 kV | 0.2 sccm | 0.3 sccm | 0.5 sccm | 0.5 sccm | 0.7 sccm |

TABLE 7

| | | PRESSURE OF He GAS | | | | |
|---|---|---|---|---|---|---|
| | | 10 Torr | 15 Torr | 20 Torr | 25 Torr | 30 Torr |
| CHUCK | 1.0 kV | 0.2 sccm | 0.3 sccm | 0.4 sccm | 0.6 sccm | 0.9 sccm |
| VOLTAGE | 1.5 kV | 0.2 sccm | 0.3 sccm | 0.4 sccm | 0.5 sccm | 0.6 sccm |
| | 2.0 kV | 0.2 sccm | 0.3 sccm | 0.4 sccm | 0.4 sccm | 0.5 sccm |
| | 2.5 kV | 0.2 sccm | 0.3 sccm | 0.4 sccm | 0.5 sccm | 0.6 sccm |

From a comparison between TABLE 4 and TABLES 5 through 7, it was noted that the leakage rate of He gas improved by performing the cleaning method of the embodiment. Moreover, it was noted that the cleaning efficiency improved by performing the third process after repeating the process group of the first and second processes.

As described above, according to the embodiments of the present invention, there is provided a cleaning method that can efficiently remove a reaction product containing titanium which has been deposited on an electrostatic chuck.

Here, the present invention is not limited to the configuration illustrated in the embodiments, but combining the configurations cited in the above embodiments with another component and the like are possible. In this regards, numerous variations and modifications are possible without departing from the scope of the present invention, and may be appropriately determined depending on such variations and modifications that may be made.

What is claimed is:

1. A cleaning method, which is performed when using a substrate processing apparatus including at least an electrostatic chuck to receive a substrate and performing a plasma process on the substrate, for removing a deposit containing titanium and attached to the electrostatic chuck, the method comprising steps of:
reducing the deposit containing titanium by plasma generated from a first process gas containing a reducing gas;
removing the reduced deposit containing titanium by plasma generated from a second process gas containing a fluorine-based gas;
removing a fluorocarbon-based deposit deposited on the electrostatic chuck when removing the reduced deposit containing titanium by the plasma generated from the second process gas containing the fluorine-based gas by plasma generated from a third process gas containing oxygen.

2. The method as claimed in claim 1, wherein the process gas containing the reducing gas includes a mixed gas of a hydrogen gas and a nitrogen gas.

3. The method as claimed in claim 1, wherein the first process gas containing the reducing gas includes an ammonia gas or a hydrogen gas.

4. The method as claimed in claim 1, wherein the second process gas containing the fluorine-based gas includes a trifluoromethan gas.

5. The method as claimed in claim 1, wherein the second process gas containing the fluorine-based gas includes a mixed gas of a trifluoromethan gas and an oxygen gas.

6. The method as claimed in claim 1, wherein the deposit containing titanium includes a titanium oxide.

7. The method as claimed in claim 1, wherein the cleaning method is performed on the substrate on which at least a titanium nitride film is deposited after performing the plasma process on the substrate by using the titanium nitride film as a mask, and
the cleaning method is performed when an integral time of the plasma process is beyond a predetermined time.

8. The method as claimed in claim 1, wherein the step of removing the fluorocarbon-based deposit deposited on the electrostatic chuck by the plasma generated from the third process gas containing oxygen after repeating a process group of a step of reducing the deposit containing titanium by the plasma generated from the first process gas containing the reducing gas and the step of removing the reduced deposit containing titanium by the plasma generated from the second process gas containing fluorine-based gas.

9. A substrate processing apparatus, comprising:
a processing chamber;
an electrostatic chuck provided in the processing chamber and configured to hold a substrate;
an electrode plate provided in the processing chamber and facing the electrostatic chuck;
a gas supply part to supply a process gas to a space sandwiched between the electrostatic chuck and the electrode plate;
a high frequency power source configured to convert the process gas supplied to the space by the gas supply part into plasma by supplying high frequency power to at least one of the electrostatic chuck and the electrode plate; and
a control unit configured to control the substrate processing apparatus, the control unit performing control of reducing a deposit containing titanium attached to the electrostatic chuck by plasma generated from a first process gas containing a reducing gas, removing the reduced deposit containing titanium by plasma generated from a second process gas containing a fluorine-based gas, and removing a fluorocarbon-based deposit deposited on the electrostatic chuck when removing the reduced deposit containing titanium by the plasma generated from the second gas containing the fluorine-based gas by plasma generated from a third process gas containing oxygen.
